(19) United States
(12) Patent Application Publication
(10) Pub. No.: US 2026/0202753 A1
(43) Pub. Date: Jul. 16, 2026

(54) TECHNIQUE FOR ASSESSING AND IMPROVING A LITHOGRAPHY MODEL

(71) Applicant: Siemens Industry Software Inc., Plano, TX (US)

(72) Inventors: Mohamed Abaidi, Saint-Egreve (FR); Ir Kusnadi, San Jose, CA (US)

(21) Appl. No.: 19/016,571

(22) Filed: Jan. 10, 2025

(51) Int. Cl. G03F 7/00; G03F 1/36; G03F 1/70

(52) U.S. Cl. CPC G03F 7/70441; G03F 1/36; G03F 1/70

(57) ABSTRACT

A technique assesses and/or improves a lithography model. A contour of a physically printed element—called the real contour—is compared to a contour of a corresponding simulated version of the printed element—called hereafter the simulated contour. The comparison of the simulated contour to the real contour includes a calculation of an indicator of a quality of the lithography model based on a difference in area between a value of a power spectral density (PSD) characterizing a roughness of the simulated contour and a value of a PSD characterizing a roughness of the real contour.

### FIELD AND BACKGROUND OF THE INVENTION

This application is generally related to the semiconductor technical field, notably to electronic design automation and, more specifically, to the detection of deformities in semiconductor processes, like lithographic processes.

Designing and fabricating electronic circuits, such as integrated microcircuits, typically involves many steps, known as a “design flow.” The particular steps of a design flow often are dependent upon the type of electronic circuit, its complexity, the design team, the fabricator or foundry that will manufacture the electronic circuit, or the like. Several steps are common to most design flows for electronic circuits.

Usually, at the end of the design flow, a “layout” design is obtained, which is a representation of the physical electronic circuits. In the layout design, the different physical components of the electronic circuit are represented as geometric elements (typically, polygons connected by lines). The geometric elements define thus the shapes that will be created by depositing one or several material layers on a substrate to manufacture the electronic circuit. The layout design can be then used as input to a lithographic process, wherein a device will manufacture the electronic circuit by photolithography. For this process, the layout design is usually used to create different masks that enable to selectively expose to radiation only desired areas of the substrate, protecting the rest of the substrate from exposure. Each mask represents thus an intended or target image that, by lithography, has to be printed on the substrate. The image that is finally physically printed on the substrate is usually referred to as the printed image.

One problematic is related to the reduction in size of the different components of the electronic circuit, and thus of the corresponding geometric elements of the layout design, which makes physically reproducing the intended layout design difficult, notably due to the diffraction of the light used during photolithography. This means that at the end, the printed image may differ from the intended image. To address this problem, techniques have been developed to improve the resolution of the image that the mask forms on the substrate during photolithography. One of these techniques is based on creating a model of the mask that is then used as input to a simulation of the photolithographic process—called hereafter the lithography model, which outputs a simulated printed image. This enables to compare the simulated printed image to the *intended image, and to adapt consequently the geometric elements forming the mask for improving a correspondence between the simulated printed image and the intended image. Of course, in such a solution, the lithography model used to simulate the lithographic process is important, as it determines the printed shape, i.e. said simulated printed image. If the lithography model is not accurate, then the physically printed image will still differ too much from the intended image. Because of this, the lithography model, i.e. the simulation of the photolithographic process, needs to be calibrated to provide realistic results.

Known in the art calibration techniques have been developed for calibrating the lithography model. In particular, some calibration techniques are based on a comparison between the contour of physical components or elements printed on a substrate and the contour of corresponding simulated components or elements appearing in the simulated printed image. Typically, scanning electron microscope (SEM) images of the physical printed components/elements are taken and compared to the simulated components/elements. An iterative process includes repeated comparisons between physically printed and simulated elements/components enables to improve the lithography model. In particular, during the iterative process, a contour extraction algorithm is used for extracting the contours of the printed components/elements from the SEM images, the contours being called hereafter the real or measured contours, which are then compared to contours of corresponding simulated components/elements obtained from the lithography model and called hereafter the simulated contours.

However, the continuous reduction of the features and size of the printed components makes the detection of deformities, such as extra prints on the substrate, or defects in the elements, a very challenging task. New methods for improving the calibration of the lithography model, and therefore the printed components, are needed.

### SUMMARY OF THE INVENTION

Various aspects of the presently disclosed invention relate to techniques for improving the lithography model, and thus, a quality and resolution of printed electronic components.

In one aspect, there is a method for assessing a lithography model configured for simulating a photolithographic process used for printing an electronic circuit on a substrate or wafer. The method includes:
a) receiving a mask created from a layout design for the electronic circuit, wherein the mask contains a pattern of geometric elements and represents a target image to be printed on a substrate using the photolithographic process;
b) receiving a contour—called hereafter the “real” or “measured” contour—of at least one of the geometric elements, wherein the real contour has been measured on a printed version of the pattern, wherein the printed version has been obtained by using the mask as input to the photolithographic process for physically printing the geometric elements on the substrate;
c) using the mask as input to the lithography model;
d) outputting, by the lithography model, a simulated printed image that includes a simulated printed version of the geometric elements—called hereafter the simulated elements, and extracting, by a contour extraction algorithm and from the simulated printed image, a contour—called hereafter “simulated” contour—for at least one of the simulated elements for which a real contour has been measured;
e) for at least one of the geometric elements for which a real contour and a simulated contour have been previously obtained or extracted, comparing its real contour to its simulated contour for assessing the lithography model and/or the simulated contour.

The method is characterized in that:
the comparison of the simulated contour to the real contour includes calculating an indicator of a quality of the lithography model based on a difference in area between a value of a power spectral density (PSD) characterizing a roughness of the simulated contour and a value of a power spectral density (PSD) characterizing a roughness of the real contour.

In another aspect, there is a method for improving a lithography model configured for simulating a photolithographic process used for printing an electronic circuit on a substrate or wafer. The method includes:
a) receiving a mask created from a layout design for the electronic circuit, wherein the mask comprises a pattern of geometric elements and represents a target image to be printed on a substrate using the photolithographic process;
b) receiving a contour—called hereafter the “real” contour—of at least one of the geometric elements, wherein the real contour has been measured on a printed version of the pattern, wherein the printed version has been obtained by using the mask as input to the photolithographic process;
c) using the mask as input to the lithography model;
d) outputting, by the lithography model, a simulated printed image that includes a simulated printed version of the geometric elements—called hereafter the simulated elements, and extracting, by a contour extraction algorithm and from the simulated printed image, a contour—called hereafter “simulated” contour—for at least one of the simulated elements for which a real contour has been received;
e) for at least one of the geometric elements for which a real contour and a simulated contour have been extracted or obtained, comparing its real contour to its simulated contour;
f) correcting the lithography model for improving a correspondence between the real contour and the simulated contour.

The method is characterized in that:
the comparison of the simulated contour to the real contour includes calculating an indicator of a quality of the lithography model based on a difference in area between a value of a power spectral density (PSD) characterizing a roughness of the simulated contour and a value of a power spectral density (PSD) characterizing a roughness of the real contour, wherein the correcting step takes place only if a value of the indicator is above a predefined threshold, the value of the indicator being thus used for triggering a correction of the lithography model.

In particular, the previously described methods may comprise using the mask as input to the photolithographic process configured for printing the pattern of geometric elements on a physical substrate and printing the geometric elements using the photolithographic process. Then, a contour extraction algorithm might be used for extracting the real contour of the at least one of the geometric elements printed on the substrate. A same contour extraction algorithm might be used for extracting the real contour and the simulated contour, or alternatively, two different contour extraction algorithms might be used. In particular, the real contours of the physically printed geometric elements might be measured using different known in the art techniques, like for instance by acquiring SEM images of the physically printed geometric elements, and extracting the real contours from the SEM images. Of course, the real contours might be extracted from images of the physically printed geometric elements obtained through other imaging techniques, like atomic force microscopy.

Preferentially, the difference in area is given by:

$${Diff}_{PSD} = \vert \sqrt{{PSD}_{simulate}} - \sqrt{{PSD}_{real}} \vert \qquad Eq . 1$$

wherein
Diff_{PSD} is the difference in area;
PSDₛᵢₘᵤₗₐₜₑ is the PSD characterizing the roughness of the simulated contour; and
PSDᵣₑₐₗ is the PSD characterizing the roughness of the real contour.

In Eq. 1, the PSD characterizing a roughness of a contour is preferentially expressed in the frequency domain, considering notably the contour as a waveform, and might be given by:

$$PSD ( f ) = \frac{{PSD}_{0}}{1 + {\vert 2 π {X}_{i} f \vert}^{2 H + 1}} \qquad Eq . 2$$

wherein
f is the frequency, i.e. the inverse of the length of the contour;
PSD₀ is the zero-frequency value of the PSD;
Xᵢ is the correlation length; and
H is the roughness exponent (Hurst exponent).

Preferentially, the predefined threshold is equal to 0.04 nm². In particular, the method includes an automatic determination of the predefined threshold, wherein a threshold determination algorithm is configured for automatically identifying, within the simulated printed image, a clean area (for instance, an area containing lines free of any issues), and for automatically calculating the difference from contours extracted from the clean area, and automatically assigned the value of the difference to the value of the predefined threshold.

Preferentially, the present method for improving a lithography model is part of an iterative process which aims to increase the correspondence between the real contour and the simulated contour. For this, steps c)-f) might be iteratively repeated until the indicator value is equal or below the predefined threshold. In order to correct the lithography model, known in the art techniques might be used, notably methods based on cost functions which aim to find values, for the simulation parameters of the lithography model, that reduce the difference between the real contour and the simulated contour. These are well-known methods which are not the subject of the present invention.

At the end, notably at the end of the iterative process, the obtained corrected lithography model might be used in an optical proximity correction (OPC) process for correcting the layout design, the latter becoming thus a corrected layout design. In particular, known in the art OPC methods that aim to correct for optical distortions by modifying the layout design might be used for correcting the layout design.

Finally, the corrected layout design might be used as input to the photolithographic process for manufacturing the electronic circuit. Thanks to the use of the claimed indicator, the process for obtaining manufactured electronic circuits that match the targeted layout design is made more efficient. Indeed, the indicator enables to efficiently assess the lithography model and the resulting simulated contour, providing a more accurate calibration of the lithography model, and thus, resulting at the end in a printed electronic circuit that accurately reproduces the intended design.

In another aspect, the present invention concerns also a non-transitory computer-readable media storing computer-executable instructions for causing one or more processors to perform the above-mentioned methods.

In a further aspect of the invention, a computing system containing a processor and an accessible memory is proposed, wherein the computing system is particularly configured to execute the above-mentioned methods.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception, and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it is advantageous to set forth definitions of certain words or phrases used throughout this patent document: the singular forms “a,” “an,” and “the” include the plural forms unless the context clearly dictates otherwise; unless the context dictates otherwise, the term “coupled” means electrically or electromagnetically connected or linked and includes both direct connections or direct links and indirect connections or indirect links through one or more intermediate elements not affecting the intended operation of the circuit; the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

Other features which are considered as characteristic for the invention are set forth in the appended claims.

Although the invention is illustrated and described herein as embodied in a technique for assessing and improving a lithography model, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a block diagram illustrating an example of a computing device that may be used to implement various embodiments of the disclosed technology;

FIG. 2 is a flowchart showing a preferred embodiment of a method for improving a lithography model according to the invention;

FIG. 3 is schematic representation of a real contour versus a simulated contour;

FIG. 4 is an illustration of a SEM image of printed geometric elements; and

FIG. 5 id a graph illustrating a difference in area between a simulated PSD and a measured PSD.

### DETAILED DESCRIPTION OF THE INVENTION

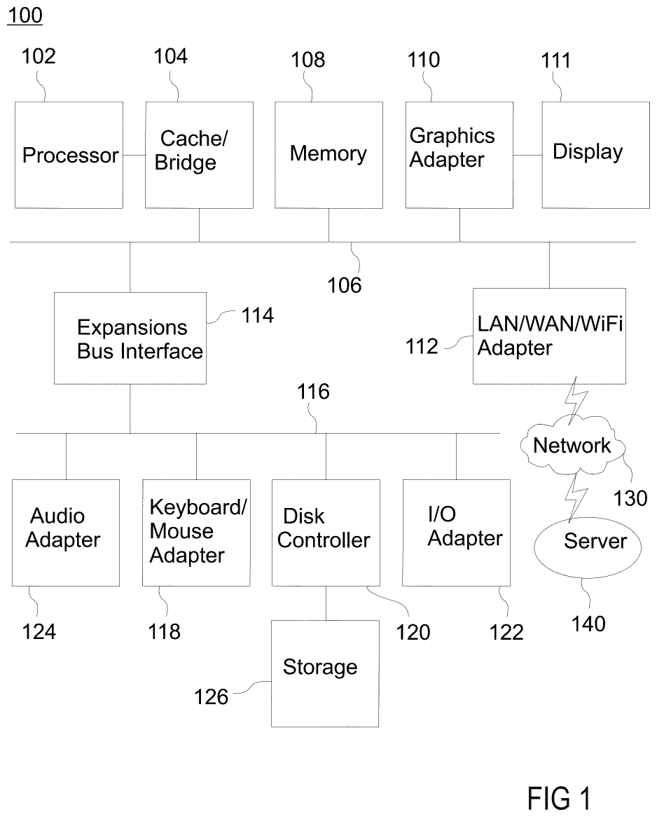

FIGS. 1 through 4, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Furthermore, in the following the solution according to the embodiments is described with respect to methods and systems for assessing and/or improving a lithography model by evaluating a quality, e.g. the accuracy and reliability, of a simulated contour, and is intended to support the design process for an integrated circuit. While numerous details are set forth for the purpose of explanation, one of ordinary skill in the art will realize that the disclosed technology may be practiced without the use of these specific details. In other instances, well-known features have not been described in detail to avoid obscuring the present disclosed technology.

Features, advantages, or alternative embodiments herein can be assigned to the other claimed objects and vice versa. In particular, some of the techniques described herein can be implemented in software instructions stored on a computer-readable medium, software instructions executed on a computer, or some combination of both. Some of the disclosed techniques, for example, can be implemented as part of an electronic design automation (EDA) tool. Such methods can be executed on a single computer or on networked computers.

Although the operations of the disclosed methods are described in a particular sequential order for convenient presentation, it should be understood that this manner of description encompasses rearrangements, unless a particular ordering is required by specific language set forth below. For example, operations described sequentially may in some cases be rearranged or performed concurrently. The detailed description sometimes uses terms like “perform”, “generate,” “create,” and “associate” to describe the disclosed methods/systems. Such terms are high-level descriptions of the actual operations that are performed. The actual operations that correspond to these terms will vary depending on the particular implementation and are readily discernible by one of ordinary skill in the art.

As used herein, the terms “integrated circuit” or “electronic circuit” refer to circuits composed of a plurality of electronic components being connected via their respective leads by conductive wires or traces. Typical examples of electronic components include, but are not limited by, CMOS resistors, transistors, capacitors, inductors, and diodes.

Also, as used herein, the term “design” is intended to encompass data describing an entire integrated circuit device. This term also is intended to encompass a smaller group of data describing one or more components of an entire device, however, such as a portion of an integrated circuit device. Still further, the term “design” also is intended to encompass data describing more than one microdevice, such as data to be used to form multiple microdevices on a single wafer or substrate.

Various examples of the disclosed technology may be implemented through the execution of software instructions by a computing system, such as a programmable computer. Referring now to the figures of the drawings in detail and first, particularly to FIG. 1 thereof, there is shown an illustrative example of a computing system 100. Such computing system 100 can for instance carry out the improvement or assessment of a lithography model according to the invention. The computing system 100 can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (1/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

The computing system 100 in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash., or RedHat Linux, may be employed if suitably modified. The operating system is modified or created in accordance with the present disclosure as described.

LAN/WAN/Wireless adapter 112 can be connected to a network 130 (not a part of computing system 100), which can be any public or private computing system network or combination of networks, as known to those of skill in the art, including the Internet. Computing system 100 can communicate over network 130 with server system 140, which is also not part of computing system 100, but can be implemented, for example, as a separate data processing system.

As mentioned earlier, the present invention tackles the problematic of the reduction in feature size of electronic components. Typically, the reduction increases that a manufacture defect (e.g. a faulty transistor or interconnecting wire) present in an integrated circuit results at the end in a faulty integrated circuit. It is therefore important that intended design be accurately reproduced on a wafer and for this, accurate lithography models are required. Assessing the lithography model is therefore a good way to prevent potentially problematic printing, and to ensure an efficient design flow.

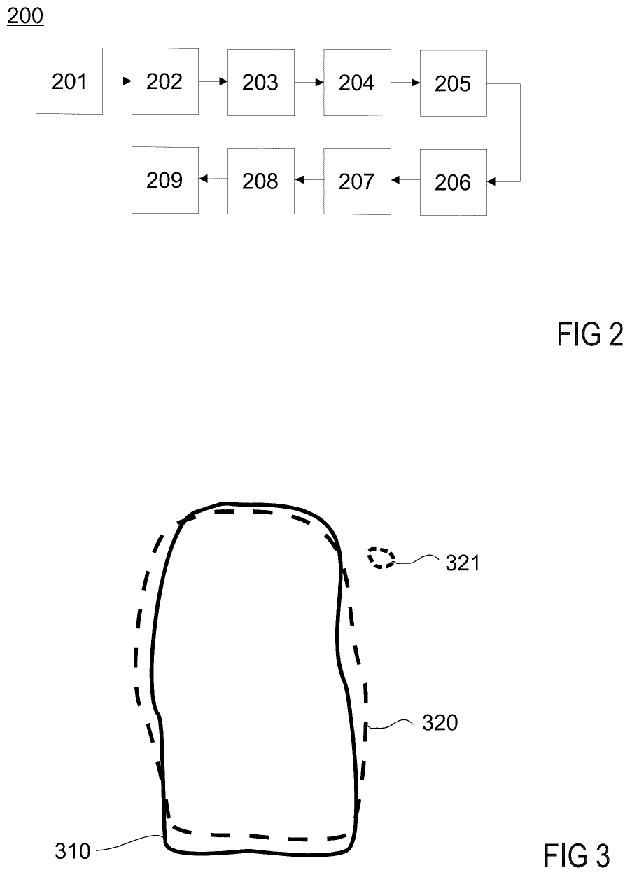

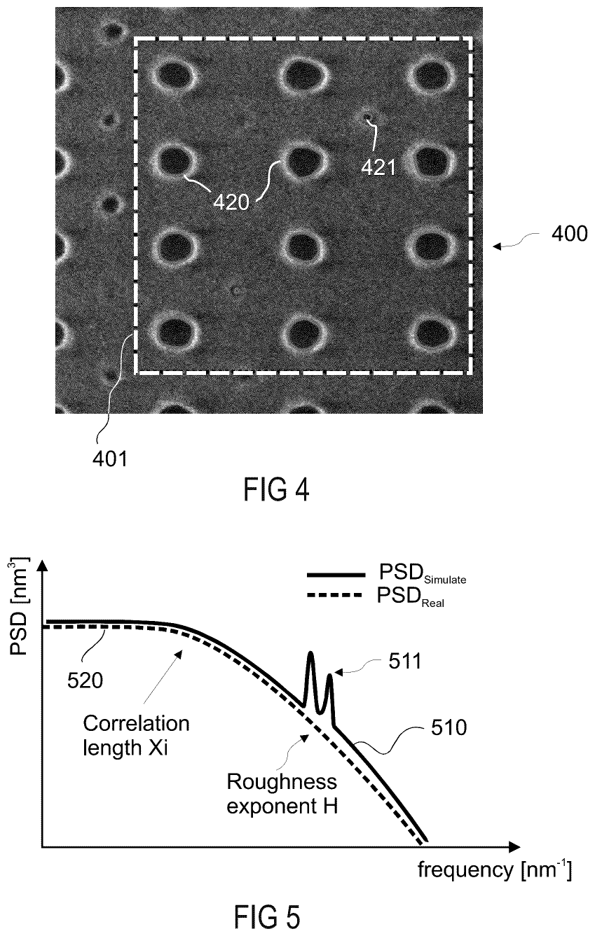

In this context, FIG. 2 illustrates a flowchart of a preferred method 200 according to the invention for assessing a quality of a lithography model, and notably for further improving the lithography model by implementing corrective measures aiming to accurately calibrate the lithography model so that it accurately mimics the real photolithographic process. The method will be explained in details hereafter in connection with FIGS. 3 to 5 which present respectively, and very schematically, a simulated contour 310 versus a real contour 320 (see FIG. 3), a SEM image 400 of geometric elements 420 that have been physically printed on a wafer or substrate (i.e. an appropriate physical surface) by means of a photolithographic process whose simulated model, i.e. the so-called lithography model, has to be assessed according to the invention (see FIG. 4), and a difference in area between a simulated PSD 510 and a measured PSD 520 (see FIG. 5).

At step 201, the computing system 100 receives a mask created from a layout design for an electronic circuit. Such a mask typically contains a pattern of geometric elements and represents a target image to be printed on a wafer or substrate. As known in the art, the mask is configured for being exposed to a radiation during the lithographic process, enabling to selectively expose to radiation only desired areas of the substrate that represent electronic components to be printed on the substrate.

At step 202, the computing system 100 receives a real contour of at least one of the geometric elements. The real contour 320 is schematically illustrated by a dashed line in FIG. 3. The real contour 320 is typically measured on a printed version of the pattern, i.e. a version obtained by using the mask as input to a device configured for implementing the photolithographic process, and by printing, via the device, the pattern on a substrate. The real contour might be then extracted from a SEM image of the printed pattern. Known in the art contour extraction algorithm might be used for the purpose.

At step 203, the computing system 100 uses the mask as input to a lithography model that is configured for simulating the photolithographic process that has been used for printing the pattern. The goal is to assess the quality of the lithography model, i.e. its accuracy and reliability, and to correct the model if the quality is not satisfying. Typically, the lithography model might be executed by the computing system 100, and its output provided by any suitable interface.

At step 204, the lithography model outputs a simulated printed image of the target image represented by the mask. The simulated printed image comprises thus a simulated printed version of the pattern, and thus of the geometric elements, which are called the simulated elements to distinguish them from the real (physically printed) elements. The computing system may comprise a contour extraction algorithm that is configured for extracting the contour of the simulated elements, called the simulated contour to distinguish it from the real (measured) contour. Such a simulated contour 310 is represented by the continuous line in FIG. 3 with respect to the real contour 320. Of course, the lithography model might also directly provide, as output, the simulated contour, and thus be able to directly extract the contour from its simulated printed image using a contour extraction algorithm. As shown in FIG. 3, the real and simulated contours may differ from each other. In particular, the physically printed version of the element may comprise an extra print 321. Alternatively, or additionally, the simulated contour(s) may comprise such an extra (simulated) print. As shown in FIG. 4, it is possible to extract or receive real contour(s) for a defined zone 401 of the pattern, and to extract for the same defined zone 401 within the simulated printed image the corresponding simulated contour(s). The zone 401 may comprise several physically printed elements 420, as well as one or several extra prints 421.

At step 205, the computing system 100 is configured for comparing the simulated contour to the real contour. This is in particular done for all or some of the elements for which a real contour and a simulated contour have been obtained. Typically, this is one for all printed elements of the predefined zone.

For the comparison, the present invention proposes to calculate an indicator that enables to assess the quality of the lithography model, and thus of the simulated contour with respect to the real contour. The indicator is based on a difference in area between a value of a PSD characterizing a roughness of the simulated contour—called hereafter the simulated PSD, and a value of a PSD characterizing a roughness of the real contour—called hereafter the real or measured PSD. Preferentially, the indicator is equal to the difference. The PSD is a signal processing technique capable of characterizing the contour roughness in the frequency-domain. That is, the spatial frequency of the contour roughness is expressed by a PSD curve that is able to quantify the variance in amplitude of the contour roughness per unit frequency. The PSD and the difference might be better understood through the graph presented in FIG. 5, which is typically characterized by a log-log scale, and which shows the simulated PSD 510 with a continuous line versus the real PSD 520 represented with a dashed line. The peaks 511 with respect to the simulated PSD 510 corresponds to extra prints in the simulation, i.e. in the simulated printed elements. The difference in area is preferentially obtained via Eq. 1, wherein the PSD is calculated via Eq. 2, wherein PSD0, H, and Xi, are represented in FIG. 5, and are commonly used to describe line edge roughness (LER) and line width roughness (LWR). Eq. 2 and the PSD curve are known to the skilled person and do not need further explanations here. The indicator, which is preferentially equal to DiffPSD, is particularly well-suited for capturing the deformities (extra-prints) in simulated contours. In particular, a deviation in DiffPSD greater than 0.04 nm² serves as a robust indicator of the degradation of the lithography model's quality and the inadequacy of the simulated contour with respect to the real contour. Advantageously, using the claimed indicator, e.g. DiffPSD as the indicator, improves the sensitivity of the assessment of the lithography model by better identifying situations where the model's performance is unsatisfactory, contributing significantly to improve the understanding of evaluation metrics in contour-based modeling. This enables to achieve a more accurate calibration of the lithography model, ensuring thus high-quality simulation, and at the end, accurate and reliable physical printing of electronic components.

Preferentially, the real PSD and the simulated PSD are calculated for all contours within the predefined zone, that is, a single real PSD curve and a single simulated PSD curve are obtained for the zone and used for assessing the lithography model, notably via Eq. 1.

At step 206, the computing system 100 is configured for automatically correcting the lithography model for improving a correspondence between the real contour and the simulated contour based on the value obtained for the comparison. Indeed, according to the present invention, the correction of the lithography model preferentially takes place only if the value of the indicator is above a predefined threshold. The latter is preferentially automatically determined by the computing system 100, which is able to automatically identify, within the simulated printed image, a clean area that is for instance free of extra prints. Then it is configured for automatically calculating the difference in area for the clean area, using the value of the obtained difference as the predefined threshold for the indicator.

At step 207, the computing system 100 preferentially repeats the steps 203-206 until the indicator is equal or below to the predefined threshold. Once the indicator is equal or below the predefined threshold, then it can be concluded that the lithography model accurately simulated the real contour. This provides a quantitative means to evaluate the accuracy and reliability of the simulated results, allowing a more rigorous assessment of the lithography model's performance.

At step 208, the computing system 100 may use the corrected lithography model in an OPC process configured for correcting the layout design so that the intended image and printed image match each other.

At step 209, the computing system 100 may output the corrected layout design via any suitable interface, the corrected layout design being then used as input to a device configured for implementing the manufacture of the electronic component(s) represented by the corrected layout design. The device is in particular configured for receiving the corrected layout design as input, and for printing electronic components represented by the layout design by means of the photolithographic process. Thanks to the correction of the lithography model in function of the value of the indicator, the physically printed electronic components will more reliably match the intended design.

Having illustrated and described the principles of the disclosed technology, it will be apparent to those skilled in the art that the disclosed embodiments can be modified in arrangement and detail without departing from such principles. In view of the many possible embodiments to which the principles of the disclosed technologies can be applied, it should be recognized that the illustrated embodiments are only preferred examples of the technologies and should not be taken as limiting the scope of the disclosed technology. Rather, the scope of the disclosed technology is defined by the following claims and their equivalents. We therefore claim as our disclosed technology all that comes within the scope and spirit of these claims.

1. A method for assessing a lithography model configured for simulating a photolithographic process used for printing an electronic circuit on a substrate, which comprises the steps of:
receiving a mask created from a layout design for the electronic circuit, the mask having a pattern of geometric elements and represents a target image to be printed on the substrate using the photolithographic process;
receiving a real contour of at least one of the geometric elements, wherein the real contour has been measured on a printed version of the pattern, wherein the printed version has been obtained by using the mask as an input to the photolithographic process;
using the mask as an input to the lithography model;
outputting, by the lithography model, a simulated printed image containing a simulated printed version of the geometric elements being simulated elements, and extracting, by a contour extraction algorithm and from the simulated printed image, a simulated contour for at least one of the simulated elements for which the real contour has been measured; and
for at least one of the geometric elements for which the real contour and the simulated contour have been previously obtained, comparing the real contour to the simulated contour for assessing the lithography model and/or the simulated contour, the comparing of the simulated contour to the real contour includes calculating an indicator of a quality of the lithography model based on a difference in area between a value of a power spectral density (PSD) characterizing a roughness of the simulated contour and a value of a PSD characterizing a roughness of the real contour.

2. The method according to claim 1, wherein the difference in area is given by:
$${Diff}_{PSD} = \vert \sqrt{{PSD}_{simulate}} - \sqrt{{PSD}_{real}} \vert$$
wherein
Diff_{PSD} is the difference in area;
PSDₛᵢₘᵤₗₐₜₑ is the PSD characterizing the roughness of the simulated contour; and
PSDᵣₑₐₗ is the PSD characterizing the roughness of the real contour.

3. The method according to claim 2, wherein the PSD characterizing a roughness of a contour is expressed in a frequency domain, considering notably the contour as a waveform, and is given by:
$$PSD ( f ) = \frac{{PSD}_{0}}{1 + {\vert 2 π {X}_{i} f \vert}^{2 H + 1}}$$
wherein
f is a frequency, i.e. an inverse of a length of the contour;
PSD₀ is a zero-frequency value of the PSD;
Xᵢ is a correlation length; and
H is a roughness exponent (Hurst exponent).

4. A method for improving a lithography model configured for simulating a photolithographic process used for printing an electronic circuit on a substrate, which comprises the steps of:
a) receiving a mask created from a layout design for the electronic circuit, the mask having a pattern of geometric elements and represents a target image to be printed on the substrate using the photolithographic process;
b) receiving a real contour of at least one of the geometric elements, wherein the real contour has been measured on a printed version of the pattern, wherein the printed version has been obtained by using the mask as an input to the photolithographic process;
c) using the mask as an input to the lithography model;
d) outputting, by the lithography model, a simulated printed image containing a simulated printed version of the geometric elements being simulated elements, and extracting, by a contour extraction algorithm and from the simulated printed image, a simulate contour for at least one of the simulated elements for which the real contour has been received;
e) comparing the real contour to the simulated contour obtained for the at least one of the geometric elements, the comparing of the simulated contour to the real contour includes calculating an indicator of a quality of the lithography model based on a difference in area between a value of a power spectral density (PSD) characterizing a roughness of the simulated contour and a value of a PSD characterizing a roughness of the real contour; and
f) correcting the lithography model for improving a correspondence between the real contour and the simulated contour, wherein the correcting step taking place only if a value of the indicator is above a predefined threshold.

5. The method according to claim 4, wherein the difference in area is given by:
$${Diff}_{PSD} = \vert \sqrt{{PSD}_{simulate}} - \sqrt{{PSD}_{real}} \vert$$
wherein
Diff_{PSD} is the difference in area;
PSDₛᵢₘᵤₗₐₜₑ is the PSD characterizing the roughness of the simulated contour; and
PSDᵣₑₐₗ is the PSD characterizing the roughness of the real contour.

6. The method according to claim 5, wherein the PSD characterizing a roughness of a contour is expressed in a frequency domain, considering notably the contour as a waveform, and is given by:
$$PSD ( f ) = \frac{{PSD}_{0}}{1 + {\vert 2 π {X}_{i} f \vert}^{2 H + 1}}$$
wherein
f is a frequency, i.e. an inverse of a length of the contour;
PSD₀ is a zero-frequency value of the PSD;
Xᵢ is a correlation length; and
H is a roughness exponent (Hurst exponent).

7. The method according to claim 4, wherein the predefined threshold is equal to 0.04 nm².

8. The method according to claim 4, which further comprises using the mask as an input to the photolithographic process configured for printing the pattern of the geometric elements on a physical substrate and printing the geometric elements, and using the contour extraction algorithm or another contour extraction algorithm for extracting the real contour.

9. The method according to claim 8, wherein the real contour is extracted from a scanning electron microscopy (SEM) image of the geometric elements printed on the substrate.

10. The method according to claim 4, which further comprises repeating the steps c)-f) until the indicator value is equal or below the predefined threshold.

11. The method according to claim 4, which further comprises using a corrected lithography model in an optical proximity correction of the layout design, the lay design becoming a corrected layout design.

12. The method according to claim 11, which further comprises using the corrected layout design as an input to the photolithographic process for manufacturing the electronic circuit.

13. A computing system, comprising:
a processor; and
a memory, the computing system configured to execute the method according to claim 1.

14. A non-transitory computer-readable medium encoded with executable instructions that, when executed, cause at least one data processing system to execute the method according to claim 1.
